(19) United States
(12) Patent Application Publication
(10) Pub. No.: US 2007/0148933 A1
(43) Pub. Date: Jun. 28, 2007

(54) Nonvolatile memory device and method of fabricating the same

(75) Inventors: Jin-Il Lee, Seongnam-si (KR); Choong-Man Lee, Seoul (KR); Sung-Lae Cho, Yongin-si (KR); Ran-Ju Jung, Seongnam-si (KR); Sang-Yeol Kang, Seoul (KR); Young-Lim Park, Anyang-si (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/512,658

(22) Filed: Aug. 30, 2006

(30) Foreign Application Priority Data
Dec. 28, 2005 (KR) 10-2005-0131856

(51) Int. Cl. H01L 21/20

(52) U.S. Cl. 438/584

(57) ABSTRACT

A method of fabricating a phase-change random-access memory (RAM) device includes forming a chalcogenide material on a substrate. A bottom contact is formed under the chalcogenide material, the bottom contact comprising TiAlN. Forming the bottom contact includes performing an atomic layer deposition (ALD) process, the ALD process including introducing an NH₃ source gas into a chamber in which the ALD process is being carried out, a flow amount of the NH₃ gas being such that the resulting bottom contact has a chlorine content of less than 1 at %. The bottom contact can include TiAlN having a crystallinity in terms of full-width half-maximum (FWHM) of less than about 0.65 degree.

### RELATED APPLICATIONS

This application relies for priority on Korean Patent Application number 10-2005-131856, filed in the Korean Intellectual Property Office on Dec. 28, 2005, the contents of which are incorporated herein in their entirety by reference.

### FIELD OF THE INVENTION

The invention relates to a phase-change random access memory (PRAM) and a method of fabricating the same, and, more particularly, to a PRAM and a method of fabricating the PRAM including a process of forming a heating element of the PRAM.

### BACKGROUND OF THE INVENTION

Phase change memory devices have recently been developed. The phase change memory device has a nonvolatile property of maintaining stored data when its power supply is interrupted. A unit cell of the phase change memory device uses a phase change material as a data storing medium. The phase change material has two stable states, namely, an amorphous state and a crystalline state, which are controlled by heat provided to the cell structure by an applied current. A generally-known phase change, or chalcogenide, material is a compound of Ge, Sb and Te, commonly referred to as a GST material (Ge—Sb—Te). Specifically, one type of GST material is Ge₂Sb₂Te₅.

When the GST material is heated for a short time at a temperature close to a melting point of the material and is then quickly cooled or quenched, the GST material is in its amorphous state. If the GST is heated for a long time at a crystallization temperature lower than the melting point and slowly cooled, the GST is in its crystalline state. The amorphous GST has a higher specific resistance than the crystalline GST. Therefore, whether the information stored in the phase change memory cell is logical ‘1’ or ‘0’ can be determined by sensing an amount of current flowing through the phase change material.

Joule heat is used as the heat supplied to the phase change material. That is, when the current is supplied to an electrode connected to the phase change material, Joule heat is generated from the electrode and supplied to the phase change material. The temperature of the heat supplied to the phase change material is dependent upon the amount of the supplied current.

FIG. 1 is a cross-sectional diagram illustrating the structure of a conventional phase change memory cell. Referring to FIG. 1, a lower insulating layer 102 is formed on a semiconductor substrate. An upper insulating layer 122 is formed on the lower insulating layer 102. A first contact hole 105 is formed through the lower insulating layer 102, and a second contact hole 125 is formed in the upper insulating layer 122. The second contact hole 125 contains a conductive upper or top contact plug 127 made of a conductive material such as tungsten (W), aluminum (Al) or copper (Cu). The first contact hole 105 contains a conductive lower or bottom contact plug and heater 113a made of a conductive material such as TiAlN, TiN, or like material.

A layer of chalcogenide GST phase change material 115 is formed in the upper insulating layer 122 on the lower insulating layer 102. A conductive upper electrode 119, made of a material such as TiN, TaN, WN or similar material, is formed on the top surface of the GST phase change material 115. The phase change material 115 is electrically connected at its bottom surface to the lower plug or heater 113a and is electrically connected at its top surface to the upper electrode 119 and the upper contact plug 127. A conductive metal pattern 129, made of a conductive material such as W, Al, Cu, or similar material, is connected to the upper contact plug 127 and the upper electrode 119.

When the memory cell is programmed, a current is applied to the structure between the metal pattern 129 and the bottom contact and heater 113a. As the current passes through the heater 113a, the resulting heat affects the state of the GST material 115 in a programmable volume or region 117. Depending on the programming process applied, the GST material in the programmable volume 117 takes on a crystalline state or an amorphous state. For example, to program the programmable volume to the crystalline state, the GST material can be heated to approximately 150 degrees C. by passing a current of approximately 0.56 mA through the material and allowing it to cool for approximately 500 ns. For example, to program the programmable volume to the amorphous state, the GST material can be heated to approximately 620 degrees C. by passing a current of approximately 1.2 mA through the material and allowing it to cool for approximately 4-5 ns.

FIG. 2A contains a schematic diagram of the memory cell of FIG. 1, and FIG. 2B is an equivalent schematic circuit diagram of a circuit in which the memory cell of FIG. 1 is used. Referring to FIGS. 2A and 2B, current from a bit line BL passes through the upper electrode 119 and the GST phase change material 115 to program the programmable volume 117 to the desired state. The GST phase change material 115 is indicated as a variable resistance. A word line is used to control a transistor 121 to enable the programming process. Current through the heater 113a heats the GST phase change material 115 to program the programmable volume 117 to the desired state. In one example configuration, the memory cell is programmed to a logic 0 state when the programmable volume 117 is in the amorphous state and the memory cell is programmed to a logic 1 state when the programmable volume 117 is in the crystalline state.

As noted above, the heating element of the PRAM memory cell is typically made of TiAlN. FIG. 3A contains a curve of resistivity of a conventional TiAlN thin film over temperature for a TiAlN thin film having a room-temperature resistivity of 4 mOhm-cm. FIG. 3B contains a curve of resistivity of a conventional TiAlN thin film over temperature for a TiAlN thin film having a room-temperature resistivity of 1 mOhm-cm. As illustrated in both graphs, at a temperature of about 500 degrees C., the resistivity of the TiAlN film drops by about 75%. The drop in resistivity results in the TiAlN film becoming a less efficient heat generating means at higher temperatures. Hence, the conventional TiAlN film is not generally efficient for use as the heating contact in a PRAM memory cell.

### SUMMARY OF THE INVENTION

According to a first aspect, the invention is directed to a method of fabricating a phase-change random-access memory (RAM) device. According to the method, a chalcogenide material is formed on a substrate. A bottom contact is formed under the chalcogenide material, the bottom contact comprising TiAlN. Forming the bottom contact includes performing an atomic layer deposition (ALD) process, the ALD process comprising introducing an NH₃ source gas into a chamber in which the ALD process is being carried out, a flow amount of the NH₃ gas being such that the resulting bottom contact has a chlorine content of less than 1 at %.

In one embodiment, a flow amount of the NH₃ gas is greater than about 24 scc.

In one embodiment, the ALD process further comprises introducing a TiCl₄ source gas into the chamber.

In one embodiment, the ALD process further comprises introducing a trimethyl aluminum (TMA) source gas into the chamber.

According to another aspect, the invention is directed to a phase-change random-access memory (PRAM) device. The device of the invention includes a chalcogenide element, the chalcogenide element comprising a material which can assume a crystalline state or an amorphous state upon application of a heating current. A contact is connected to a region of the chalcogenide material defining a programmable volume of the chalcogenide material, the contact comprising TiAlN having a concentration of chlorine less than 1 % at.

According to another aspect, the invention is directed to a phase-change random-access memory (PRAM) device. The device of the invention includes a chalcogenide element, the chalcogenide element comprising a material which can assume a crystalline state or an amorphous state upon application of a heating current. A contact is connected to a region of the chalcogenide material defining a programmable volume of the chalcogenide material, the contact comprising TiAlN having a crystallinity in terms of full-width half-maximum (FWHM) of less than about 0.65 degree.

### BRIEF DESCRIPTION OF THE DRAWINGS

The foregoing and other objects, features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention. In the drawings, the thickness of layers and regions are exaggerated for clarity.

FIG. 1 is a cross-sectional diagram illustrating the structure of a conventional phase change memory cell.

FIG. 2A contains a schematic diagram of the memory cell of FIG. 1.

FIG. 2B is an equivalent schematic circuit diagram of a circuit in which the memory cell of FIG. 1 is used.

FIG. 3A contains a curve of resistivity of a conventional TiAlN thin film over temperature for a TiAlN thin film having a room-temperature resistivity of 4 mOhm-cm.

FIG. 3B contains a curve of resistivity of a conventional TiAlN thin film over temperature for a TiAlN thin film having a room-temperature resistivity of 1 mOhm-cm.

FIG. 4 contains a schematic process timing diagram for a process of forming TiAlN used in a heater or contact in a PRAM device, according to an embodiment of the invention.

FIG. 5 contains a curve of resistivity of two TiAlN thin films over temperature for TiAlN thin films having a room-temperature resistivity of 2 mOhm-cm (indicated by circles) and 1 mOhm-cm (indicated by squares) and formed by the process of the invention.

FIG. 6 contains a graph of the effect of ammonia flow rate on the chlorine content in a TiAlN thin film.

FIG. 7 contains a graph of the effect of deposition temperature on the chorine content and aluminum content in a TiAlN thin film.

FIG. 8 is a graph illustrating the effect of ammonia flow rate on crystallinity of the resulting TiAlN film in the form of X-ray diffraction curves.

FIGS. 9A and 9B contain graphs illustrating the effect of the ammonia flow rate used in producing the TiAlN film in the heater contact of a PRAM cell on the operation of the PRAM cell.

FIG. 10 contains a table summarizing compositional variation in TiAlN thin films.

FIG. 11 contains a schematic cross-sectional view of a structure of a PRAM device with the TiAlN heater contact according to an embodiment of the invention.

FIG. 12 contains a schematic cross-sectional diagram of an embodiment of a PRAM cell using the heater contact according to the invention.

FIG. 13 contains a schematic cross-sectional diagram of another embodiment of a PRAM cell using the heater contact according to the invention.

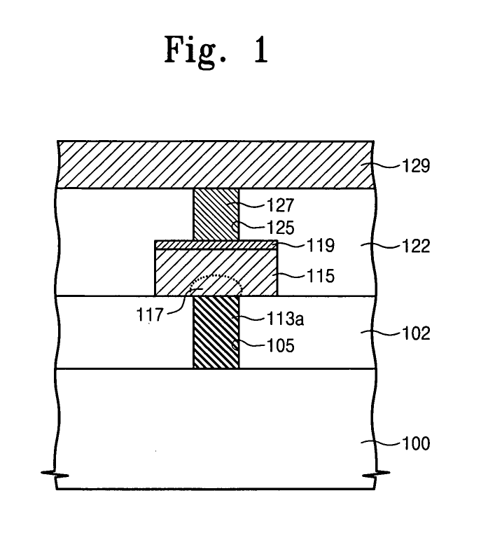

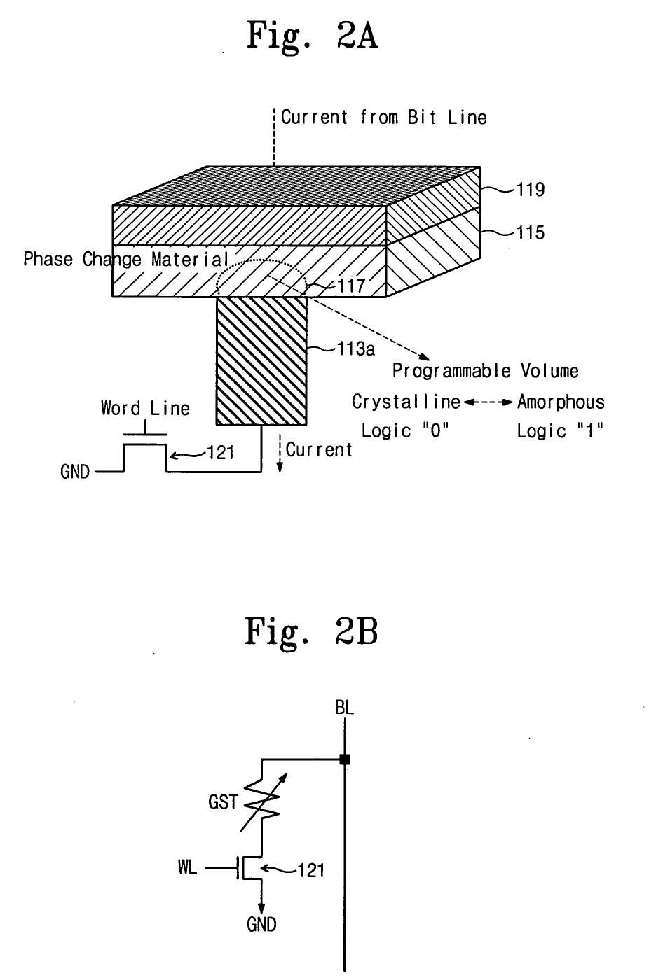

### DETAILED DESCRIPTION OF PREFERRED EMBODIMENTS OF THE INVENTION

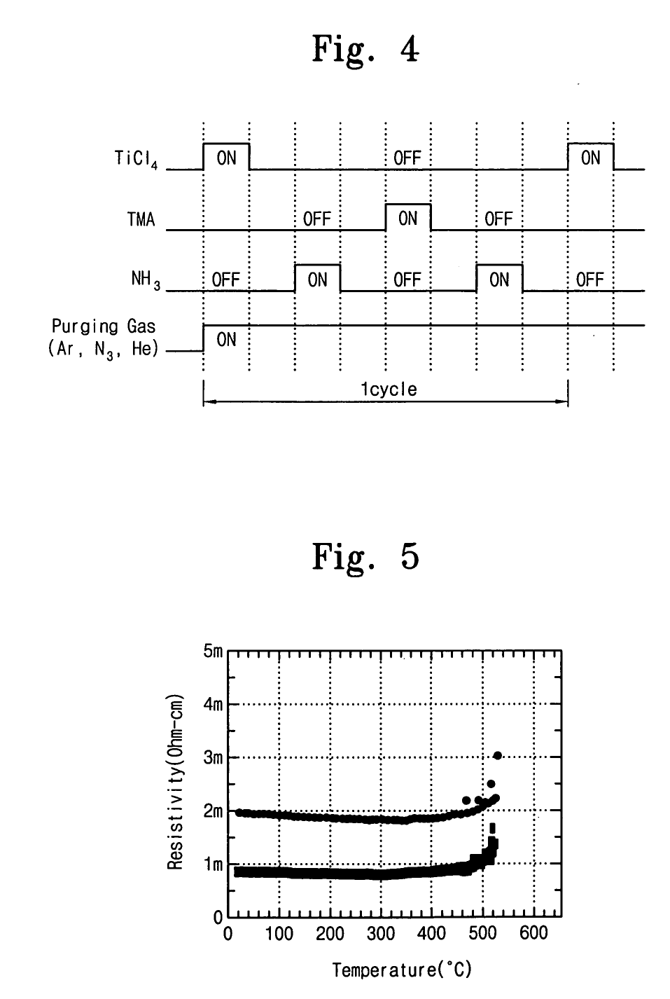

FIG. 4 contains a schematic process timing diagram for a process of forming TiAlN used in a heater or contact in a PRAM device, according to an embodiment of the invention. Referring to FIG. 4, the TiAlN film is formed by an atomic layer deposition (ALD) process in which three source gases and a purge gas are introduced into a process chamber according to the timing illustrated in the timing diagram. Titanium tetrachloride (TiCl₄), can be used as the source gas for titanium. Trimethyl aluminum (TMA) can be used as the source gas for aluminum. Ammonia (NH₃) can be used as the source gas for nitrogen. The purge gas can be Ar, N₃ or He. As shown in the timing diagram, the three source gases are pulsed on and off. In one embodiment, the purge gas is turned on at the beginning of the process and remains turned on throughout the process.

In one particular embodiment, the TiCl4 gas is turned on and then turned off. It is then purged from the process chamber by the purge gas. Next, the ammonia gas is turned on and off and purged from the chamber. Next, the TMA gas is turned on and off and then purged from the chamber. Next, the ammonia gas is turned back on and then off again and then purged from the chamber. Finally, the TiCl4 is turned on and then off and then is purged from the chamber to complete the cycle. In one embodiment, the process is carried out at a deposition temperature of 450 degrees C. and a pressure of 1 Torr.

The timing diagram of FIG. 4 illustrates one cycle in the ALD process used to form the entire TiAlN contact. Many cycles can be repeated as desired to form the required contact.

The total dose of a gas applied to the layer being formed is determined by the flow rate of the associated source gas and the amount of time the source gas is turned on. According to the invention, the ammonia gas is turned on twice for two seconds each time. According to the invention, the flow rate of the ammonia gas is set to approximately 725 sccm or higher. That is, each time the ammonia gas is turned on for two seconds, a dose of ammonia at 725×(2/60)=24.167 scc is delivered to the chamber.

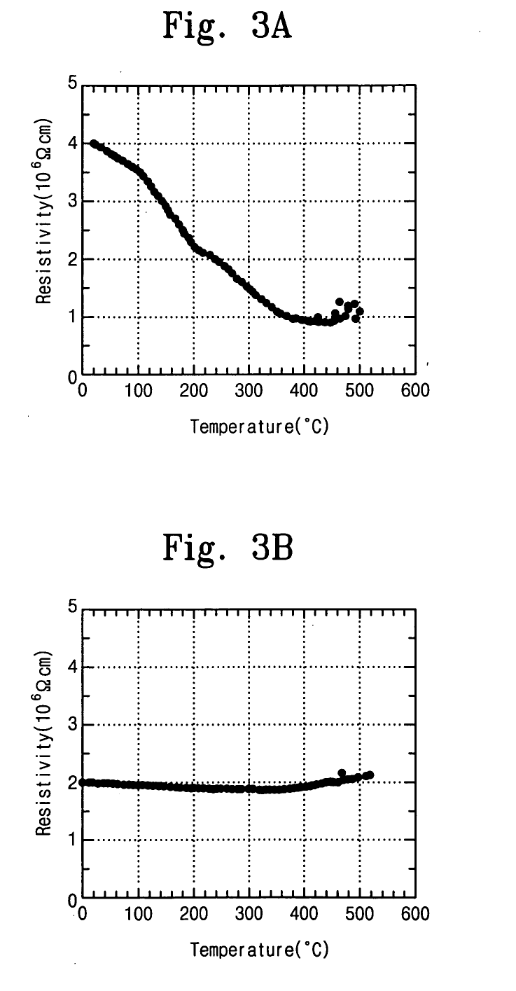

FIG. 5 contains a curve of resistivity of two TiAlN thin films over temperature for TiAlN thin films having a room-temperature resistivity of 2 mOhm-cm (indicated by circles) and 1 mOhm-cm (indicated by squares) and formed by the process of the invention. The TiAlN films of FIG. 5 are formed according to the invention using an ALD process according to the process timing diagram of FIG. 4, with an ammonia flow rate of 725 sccm. A comparison of FIG. 5 to FIGS. 3A and 3B, which show resistivity over temperature for TiAlN thin films formed using an ammonia flow rate of 450 sccm, shows that using the process of the invention to form the thin films with the higher ammonia flow rate results in thin films which do not lose their resistivity over temperatures up to 500 degrees C. Because the resistivity of the TiAlN films formed according to the invention maintain their resistivity over temperature, they are serve as more efficient heating contacts for a PRAM cell.

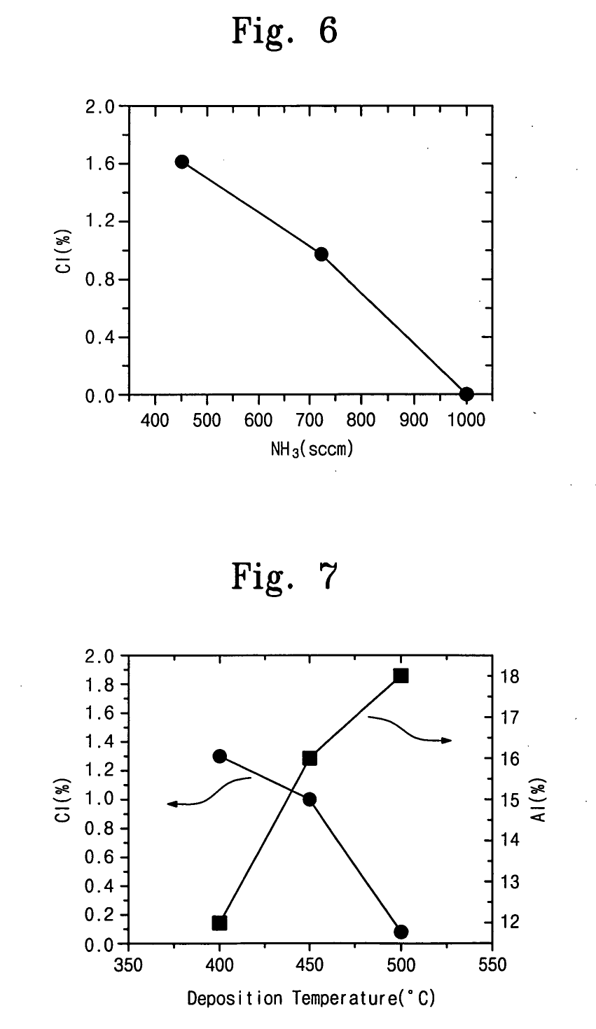

The TiAlN film made in accordance with the invention maintains its resistivity over temperature because the higher ammonia flow rate results in a film having a lower chlorine content than that produced using a lower flow rate, such as the films indicated in FIGS. 3A and 3B. FIG. 6 contains a graph of the effect of ammonia flow rate on the chlorine content in a TiAlN thin film. Referring to FIG. 6, it is seen that as the flow rate of ammonia increases, the chorine content in the resulting TiAlN film decreases. In particular, it is noted from the graph of FIG. 6 that at and above the example flow rate of 725 sccm, the chlorine content in the resulting film is below about 1 at %.

FIG. 7 contains a graph of the effect of deposition temperature on the chorine content and aluminum content in a TiAlN thin film. Referring to FIG. 7, it is seen that as the deposition temperature increases, the resulting aluminum content increases, and the resulting chlorine content decreases. The graph of FIG. 7 is based on depositions carried out using an ammonia flow rate of about 725 sccm, in accordance with the invention. It is also noted that above a deposition temperature of about 450 degrees C., the chlorine content is below about 1 at %. Also, there is an upper limit on the aluminum content of about 20 at % due to a decrease in resistivity with deposition temperature. As illustrated in the graph of FIG. 7, at a deposition temperature of about 450 to 500 degrees C., good results are achieved in that the aluminum content in the resulting film is below about 20 at % and the chlorine content in the film is below about 1 at %.

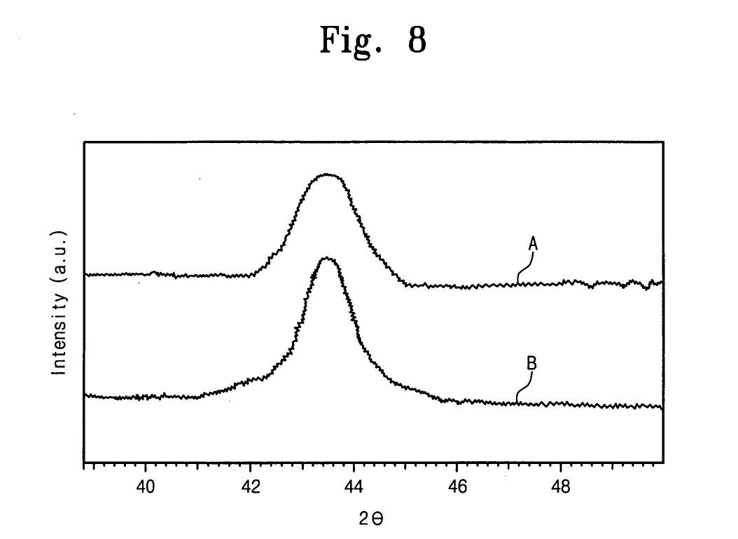

FIG. 8 is a graph illustrating the effect of ammonia flow rate on crystallinity of the resulting TiAlN film in the form of X-ray diffraction curves, with the horizontal axis indicating the 2θ angle and the vertical axis indicating intensity. The curve labeled A is for a sample film created using an ammonia flow rate of 450 sccm, and the curve labeled B is for a sample film created using an ammonia flow rate of 725 sccm in accordance with the process of the invention. As illustrated in the curves of FIG. 8, the film formed using the higher ammonia flow rate of the invention of 750 sccm has higher crystallinity than the film formed using the lower ammonia flow rate of 450 sccm. Specifically, the crystallinity of the sample of curve B in terms of full-width half maximum (FWHM) using the higher ammonia flow rate according to the invention is about 0.65 degree. In comparison, the crystallinity of the sample of curve A in terms of FWHM using the lower ammonia flow rate is about 1.0112. Also, the sample film of curve B also exhibits higher 2θ intensity of 43.25974 than the 2θ intensity of the sample film of curve A, i.e., 43.31619.

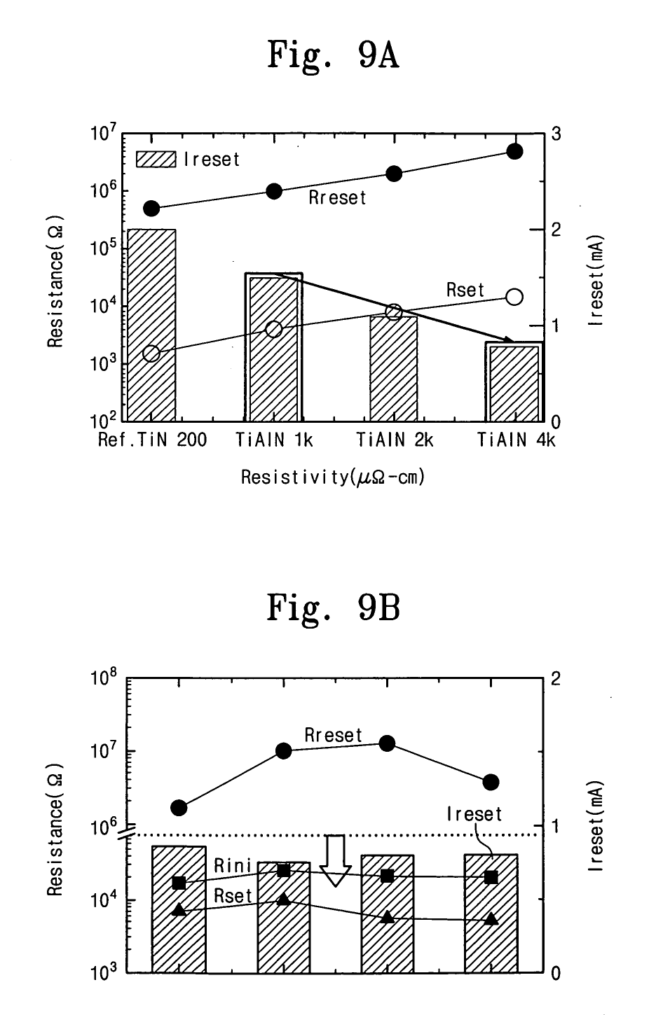

FIGS. 9A and 9B contain graphs illustrating the effect of the ammonia flow rate used in producing the TiAlN film in the heater contact of a PRAM cell on the operation of the PRAM cell. Specifically, FIG. 9A illustrates the set resistance Rset, reset resistance Ireset and reset programming current Ireset of the PRAM cell for four different types of TiAlN heater contacts formed using an ammonia flow rate of 450 sccm. FIG. 9B illustrates the set resistance Rset, initial resistance Rini, reset resistance Rreset and reset programming current Ireset of the PRAM cell for four different types of TiAlN heater contacts formed using an ammonia flow rate of 725 sccm, in accordance with the invention. As illustrated in FIG. 9A, the four different materials are TiN 200 (resistivity 200 μOhm-cm), TiAlN 1 k (resistivity 1 k μhm-cm), TiAlN 2 k (resistivity 2 k μOhm-cm) and TiAlN 4 k (resistivity 4 k μOhm-cm). The reset resistance Rreset and set resistance Rset are both higher for the four materials in the order as listed. The reset current Ireset is lower for each material in the order as listed. It is noted that the reset current Ireset for only the material TiAlN 4 k is below 1 mA. That is, the higher the set resistance Rset and reset resistance Rreset, the lower the required reset current Ireset. It is also noted that the reset current Ireset for the TiAlN 1 k film, having a resistivity of 1 mΩcm is about 1.5 mA.

FIG. 9B shows the graphs for the same four materials illustrated in FIG. 9A, produced using the higher ammonia flow rate of 725 sccm of the invention. As noted in FIG. 9B, in general, all four materials have about equal or lower reset current Ireset than their counterparts made using the lower ammonia flow rate. Specifically, the reset current Ireset for the first three materials is lower than the reset current Ireset of the corresponding material of FIG. 9A. The reset current Ireset of the fourth material TiAlN 4 k (resistivity 4 mΩcm) is about the same as that of its counterpart of FIG. 9A, namely, about 0.8 mA. The reset current Ireset of the TiAlN 1 k material (resistivity 1 mΩcm) is about 0.8 mA.

Referring to the graphs of FIGS. 9A and 9B, it is noted that at the lower ammonia flow rate of 450 sccm, the resistivity of the materials shows an undesirable decreasing tendency. Using the higher ammonia flow rate of the invention, the resistivity characteristic is approximately flat over the different materials. Hence, using the higher ammonia flow rate of the invention, the reset current Ireset is essentially insensitive to the material being formed. Also, with the higher ammonia flow rate all of the materials have similar resistivity characteristics to those of the TiAlN 4 k material formed using the lower ammonia flow rate.

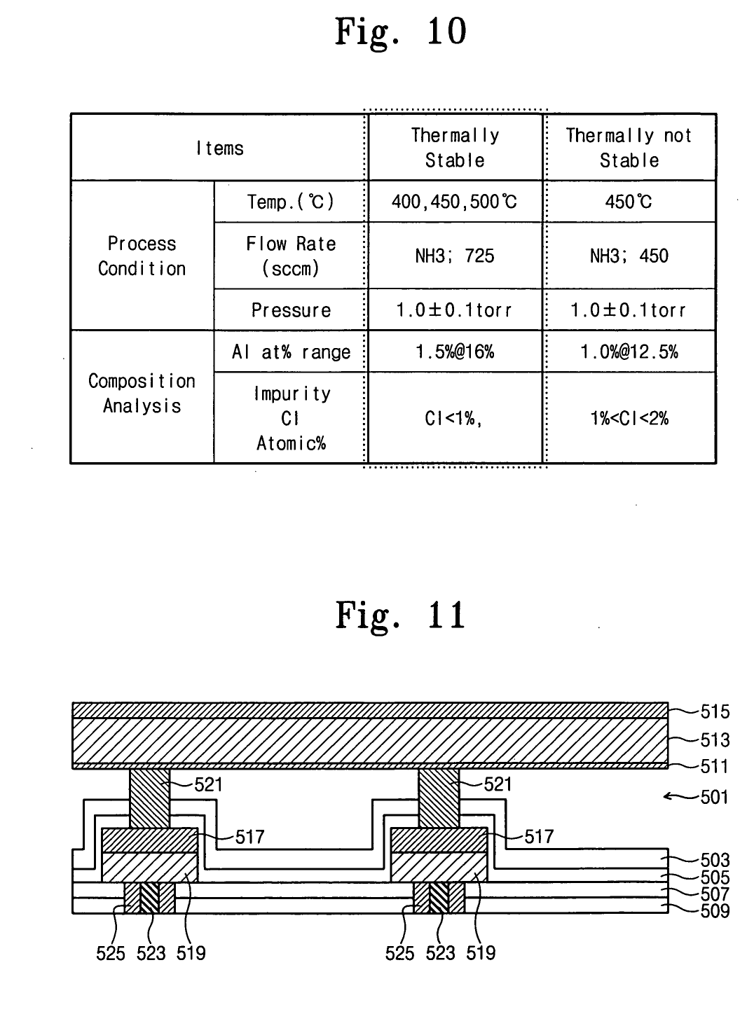

FIG. 10 contains a table summarizing compositional variation in TiAlN thin films comparing the characteristics of the thin films manufactured according to the invention with those of thin films manufactured by a prior approach. Referring to FIG. 10, a thermally stable TiAlN thin film is fabricated using the higher ammonia flow rate of 725 sccm, according to the invention. That is, a TiAlN thin film manufactured according to the invention has stable or near-constant resistivity over temperature, particularly at high temperature. A thermally unstable thin film, that is, a film whose resistivity characteristic drops substantially over temperature and particularly at high temperature, is fabricated using a prior approach with an ammonia flow rate of 450 sccm. As noted in the table of FIG. 10, the film made by the process of the invention has an aluminum composition of 1.5 at % to 16 at %, and the film made by the prior approach has an aluminum content of 1.0 at % to 12.5 at %. The film made by the process of the invention has a chlorine composition of less than 1 at %, and the film made by the prior approach has a chlorine content of between 1.0 and 2.0 at %.

FIG. 11 contains a schematic cross-sectional view of a structure of a PRAM device with the TiAlN heater contact according to an embodiment of the invention. The PRAM structure includes a layer of SiN 509 at a thickness of approximately 500 Å. A SiON layer 507 at a thickness of approximately 500 Å is formed over the layer 509. The TiAlN heater contacts 523 of the two illustrated memory cells are formed through the layers 507 and 509. The TiAlN heater contacts 523, at a diameter or width of approximately 50±5 nm are surrounded by SiON/SiN material of a diameter or width of approximately 90± nm. A layer 505 of SiN at approximately 200 Å thickness is formed over the layer 507 and conformally over the GST phase change material 519 and the upper electrode 517. The GST material 519 and upper electrode 517 are formed to a total thickness of approximately 1,700 Å and to a width of approximately 260±5 nm. A PEOX layer 503 is formed over the layer 505 conformally with the layer 505. A layer 501 of undoped silica glass (USG) is formed with plasma enhanced tetra-ethoxy-silane (PETEOS) over the layer 503 to a thickness of approximately 2,600 Å. A metal pattern including a layer 511 of Ti at a thickness of approximately 100 Å, a layer 513 of Al at a thickness of approximately 3,000 Å and a layer 515 of Ti/TiN at 150 Å/650 Å is formed over the USG layer 501. The distance between the top of the upper electrode 517 and the layer 511 is approximately 1500 Å. The tungsten (W) plug 521 is formed at a width or diameter of approximately 120±to connect the layer 511 to the upper electrode 517.

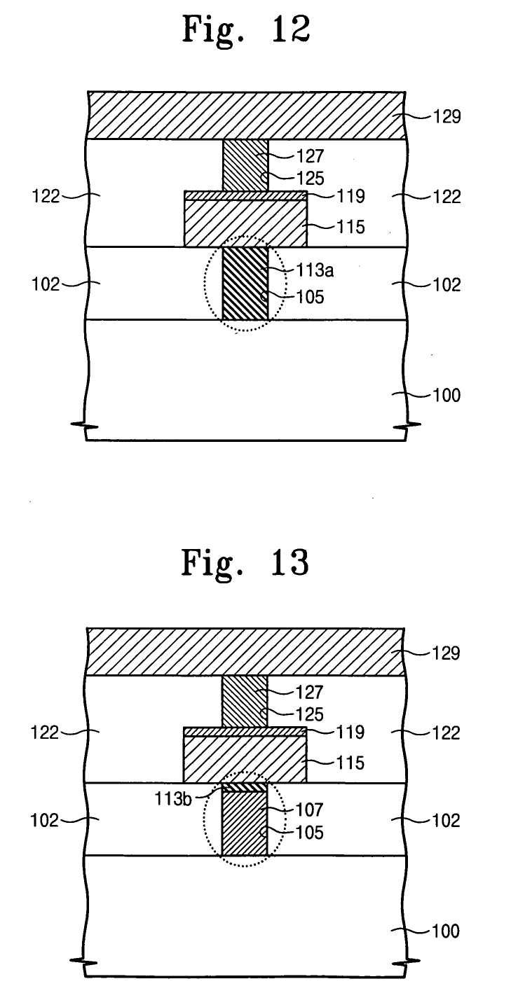

FIG. 12 contains a schematic cross-sectional diagram of an embodiment of a PRAM cell using the heater contact according to the invention. FIG. 13 contains a schematic cross-sectional diagram of another embodiment of a PRAM cell using the heater contact according to the invention. Referring to FIGS. 12 and 13, a lower insulating layer 102 is formed on a substrate 100. An upper insulating layer 122 is formed on the lower insulating layer 102. A phase change material layer 115 is formed on the lower insulating layer 102 in the upper insulating layer 122. An upper electrode 119, made of a material such as TiN, TaN, WN or other such material, is formed on the phase change material layer 115. A second contact hole 125 is formed through the upper insulating layer 122 and contacting the top surface of the upper electrode 119. A conductive contact plug 127 made of a material such as W, Al, Cu or other such material is formed in the second contact hole 125 in contact with the top surface of the upper electrode 119. A metal pattern 129, made of a material such as W, Al, Cu or other such material, is formed on the upper insulating layer 122 in contact with the top surface of the contact plug 127. A first contact hole 105 is formed through the lower insulating layer 102 in contact with the bottom surface of the phase change material layer 115.

The difference between the embodiments of FIGS. 12 and 13 is in the bottom contact heater used to program the phase change material 115. In the embodiment of FIG. 12, a heater contact 113 made of TiAlN, TiN, or other such material, is formed in accordance with the process of the invention to fill the entire first contact hole 105. In the embodiment of FIG. 13, a supplementary electrode or contact 107 is first formed in the first contact hole 105. Then, the heater contact 113b made of TiAlN, TiN, or other such material, is formed in accordance with the process of the invention in the first contact hole 105 to a thickness of a few to a few tens of angstroms on top of the supplementary electrode or contact 107. The heater contact 113b makes contact with the bottom surface of the phase change material 115.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. A method of fabricating a phase-change random-access memory (RAM) device, comprising:
forming a chalcogenide material on a substrate; and
forming a bottom contact under the chalcogenide material, the bottom contact comprising TiAlN, forming the bottom contact comprising performing an atomic layer deposition (ALD) process, the ALD process comprising introducing an NH₃ source gas into a chamber in which the ALD process is being carried out, a flow amount of the NH₃ gas being such that the resulting bottom contact has a chlorine content of less than 1 at %.

2. The method of claim 1, wherein a flow amount of the NH₃ gas is greater than about 24 scc.

3. The method of claim 1, wherein the ALD process further comprises introducing a TiCl₄ source gas into the chamber.

4. The method of claim 1, wherein the ALD process further comprises introducing a TMA source gas into the chamber.

5. A phase-change random-access memory (PRAM) device, comprising:
a chalcogenide element, the chalcogenide element comprising a material which can assume a crystalline state or an amorphous state upon application of a heating current; and
a contact connected to a region of the chalcogenide material and defining a programmable volume of the chalcogenide material, the contact comprising TiAlN having a concentration of chlorine less than 1 % at.

6. A phase-change random-access memory (PRAM) device, comprising:
a chalcogenide element, the chalcogenide element comprising a material which can assume a crystalline state or an amorphous state upon application of a heating current; and
a contact connected to a region of the chalcogenide material and defining a programmable volume of the chalcogenide material, the contact comprising TiAlN having a crystallinity in terms of full-width half-maximum (FWHM) of less than about 0.65 degree.
